(19) United States
(12) Patent Application Publication
(10) Pub. No.: US 2026/0096310 A1
(43) Pub. Date: Apr. 2, 2026

(54) DISPLAY PANEL AND METHOD OF MANUFACTURING DISPLAY PANEL

(71) Applicant: HKC CORPORATION LIMITED, SHENZHEN (CN)

(72) Inventors: Yao LI, SHENZHEN (CN); Pei XU, SHENZHEN (CN)

(73) Assignee: HKC CORPORATION LIMITED, SHENZHEN (CN)

(21) Appl. No.: 19/321,178

(22) Filed: Sep. 6, 2025

(30) Foreign Application Priority Data
Sep. 30, 2024 (CN) 202411389827.6

(51) Int. Cl. H10K 59/127; H10K 59/12; H10K 102/00

(52) U.S. Cl. CPC H10K 59/1275; H10K 59/1201; H10K 2102/351; H10K 2102/361

(57) ABSTRACT

A display panel includes: a glass substrate, a plurality of light emitting units, a plurality of first bonding portions, a silicon-based driver substrate, a plurality of deformation layers. Each deformation layer is at least partially disposed between a respective one first bonding electrode and a hole sidewall of a respective one first conductive through hole. In response to a temperature of the deformation layer being lower than a predetermined temperature, the deformation layer is deformed, and a thickness of the deformation layer is less than a spacing between the first bonding electrode and the hole sidewall of the first conductive through hole.

### CROSS REFERENCE TO RELATED APPLICATIONS

The present application claims the priority of the Chinese patent application No. 202411389827.6, filed on Sep. 30, 2024, contents of which are incorporated herein by its entireties.

### TECHNICAL FIELD

Embodiments of the present disclosure relate to the technical field of displaying, and more specifically, to a display panel and method of manufacturing display panel.

### BACKGROUND

A monocrystalline silicon driver backplane is a driver substrate which takes a semiconductor device formed based on a complementary metal oxide semiconductor (CMOS) process as a driver unit. Compared to an active-matrix organic light-emitting diode (AMOLED) panel which takes an amorphous silicon, a microcrystalline silicon, or a low-temperature polycrystalline silicon thin-film transistor as the backplane, the monocrystalline silicon driver backplane may have a higher carrier mobility. Therefore, a silicon-based organic light-emitting diode (OLED) display panel may be a best performance display panel to be used in AR/VR products.

Currently, for the silicon-based OLED display panel, an externally-bound display chip may be integrated into the silicon-based driver backplane. A preparation method thereof is to perform evaporation to form the OLED device on the silicon-based driver substrate. Specific processes include: firstly performing deposition to form an anode, then preparing a pixel defining layer, and then performing deposition to successively form an organic light emitting layer and a cathode. In this way, smaller-sized pixel units may be prepared, and displaying finesse even better than retina may be achieved, such that a high resolution, high integration, lower power consumption, a small size, and a light weight, can be achieved.

However, direct evaporation to form the OLED device on silicon-based driver substrate may affect a silicon-based driver circuit, resulting in damage to the driver circuit, such that the driver circuit may be unusable, increasing manufacturing costs.

### SUMMARY

The present disclosure provides a display panel and a method of manufacturing the display panel, so as to solve the technical problem of circuit damages caused by direct evaporation to form the OLED device on silicon-based driver substrate.

In a first aspect, the present disclosure provides a display panel, including:
a glass substrate, including a first surface and a second surface opposite to the first surface, where the glass substrate defines a plurality of conductive through holes extending from the first surface to the second surface; the plurality of the conductive through holes includes a plurality of first conductive through holes;
a plurality of light emitting units, arranged on the first surface of the glass substrate; where each of the plurality of light emitting units includes an anode electrode, an organic light emitting layer, and a cathode electrode that are stacked sequentially in a direction away from the glass substrate;
a plurality of first bonding portions, where each of the plurality of first bonding portions is received in a respective one of the plurality of first conductive through holes; each of the plurality of first bonding portions is electrically connected, through the respective first conductive through hole, to the anode electrode of a respective one of the plurality of light emitting units;
a silicon-based driver substrate, arranged at a side of the second surface of the glass substrate and including a plurality of first bonding electrodes; where each of the plurality of first bonding electrodes; is at least partially embedded in a respective one of the plurality of first conductive through holes and is electrically connected to a respective one of the plurality of first bonding portions; each of the plurality of first bonding electrodes is spaced apart manner from a hole sidewall of the respective first conductive through hole;
a plurality of deformation layers, where each of the plurality of deformation layers is at least partially disposed between a respective one of the plurality of first bonding electrodes and the hole sidewall of the respective first conductive through hole; in response to a temperature of the deformation layer being lower than a predetermined temperature, the deformation layer is deformed, and a thickness of the deformation layer is less than a spacing between the first bonding electrode and the hole sidewall of the first conductive through hole.

In a second aspect, the present disclosure provides a method of manufacturing a display panel, including:
providing a silicon-based driver substrate; where the silicon-based driver substrate includes a plurality of first bonding electrodes;
   providing a glass substrate; where the glass substrate includes a first surface and a second surface opposite to the first surface; the glass substrate defines a plurality of conductive through holes extending from the first surface to the second surface; the plurality of conductive through holes includes a plurality of first conductive through holes;
   coating a deformation material on at least a sidewall surface of each of the plurality of first bonding electrodes to form a deformation layer;
   bonding a side of the second surface of the glass substrate to the silicon-based driver substrate; and embedding each of the plurality of first bonding electrodes coated with the deformation layer into a respective one of the plurality of first conductive through holes;
   filling a conductive material into the plurality of first conductive through holes to form a plurality of first bonding portions; and electrically connecting each of the plurality of first bonding portions to a respective one of the plurality of first bonding electrodes;
   depositing a plurality of anode electrodes, a plurality of organic light emitting layers and a plurality of cathode electrodes sequentially on the first surface of the glass substrate to form a plurality of light emitting units; electrically connecting, through the respective first conductive through hole, each of the plurality of first bonding portions to a respective one of the plurality of anode electrodes.

In some embodiments, the deformation layer is a conductive deformation layer, the deformation material is a conductive deformation material; the coating a deformation material on at least a sidewall surface of each of the plurality of first bonding electrodes to form a deformation layer, includes:
coating the conductive deformation material on the sidewall surface of each of the plurality of first bonding electrodes to form a first conductive deformation layer; coating the conductive deformation material on a top wall surface of each of the plurality of first bonding electrodes to form a second conductive deformation layer; where a thickness of the second conductive deformation layer is greater than or equal to a thickness of the first conductive deformation layer.

Alternatively, coating the conductive deformation material on a sidewall surface of each of the plurality of first bonding electrodes to form a first conductive deformation layer; depositing the conductive deformation material on a sidewall surface of each of the plurality of first conductive through holes and removing a portion of the conductive material located near the second surface, so as to form a third conductive deformation layer.

### BRIEF DESCRIPTION OF THE DRAWINGS

FIG. 1 is a structural schematic view of a display panel according to a first embodiment of the present disclosure.

FIG. 2 is an enlarged view of a portion A in the display panel shown in FIG. 1.

FIG. 3 is a structural schematic view of a conductive deformation layer shown in FIG. 2, after being deformed.

FIG. 4 is an enlarged view of the portion A in the display panel according to a second embodiment of the present disclosure.

FIG. 5 is a structural schematic view of the conductive deformation layer shown in FIG. 4, after being deformed.

FIG. 6 is a flow chart of a method of manufacturing the display panel according to an embodiment of the present disclosure.

FIG. 7 is a structural schematic view of a component in an operation S1 shown in FIG. 6.

FIG. 8 is a structural schematic view of a component in an operation S2 shown in FIG. 6.

FIG. 9 is a structural schematic view of a component in an operation S3 shown in FIG. 6.

FIG. 10 is a structural schematic view of a component in an operation S4 shown in FIG. 6.

FIG. 11 is a structural schematic view of a component in an operation S5 shown in FIG. 6.

FIG. 12 is a structural schematic view of a component in an operation S6 shown in FIG. 6.

FIG. 13 is a structural schematic view of a component in an operation S31 shown in FIG. 6.

FIG. 14 is a structural schematic view of a component in an operation S31A shown in FIG. 6.

FIG. 15 is a structural schematic view of a component in an operation S32A shown in FIG. 6.

### REFERENCE NUMERALS IN THE DRAWINGS

1—glass substrate; 2—light emitting unit; 3—pixel defining layer; 4—first bonding portion; 5—deformation layer; 6—silicon-based driver substrate; 7—second bonding portion; 8—encapsulation layer; 11—first surface; 12—second surface; 13—conductive through hole; 21—anode electrode; 22—organic light emitting layer; 23—cathode electrode; 50—conductive deformation layer; 51—first conductive deformation layer; 52—second conductive deformation layer; 53—third conductive deformation layer; 61—first bonding electrode; 62—silicon substrate; 63—driver circuit; 64—protection layer; 65—second bonding electrode; 131—first conductive through hole; 132—second conductive through hole.

### DETAILED DESCRIPTIONS

The technical solutions in the embodiments of the present disclosure will be clearly and completely described below by referring to the accompanying drawings in the embodiments of the present disclosure. Apparently, the described embodiments are only a part of, not all of, the embodiments of the present disclosure. All other embodiments, which are obtained by any ordinary skilled person in the art based on the embodiments in the present disclosure without making creative work, shall fall within the scope of the present disclosure.

Terms “first”, “second”, and “third” in the present disclosure are used for descriptive purposes only and are not to indicate or imply relative importance or implicitly specifying the number of technical features. Therefore, a feature defined with “first”, “second”, “third” may include at least one such feature, either explicitly or implicitly. In the description of the present disclosure, “a plurality of” means at least two, such as two, three, and so on, unless otherwise expressly and specifically limited. All directional indications (such as up, down, left, right, front, rear . . . ) in the embodiments of the present disclosure are only used to explain a relative positional relationship and movement between components at a particular attitude (the attitude as shown in the accompanying drawings). The directional indication may be changed accordingly when the particular attitude is changed. Furthermore, terms “include” and “have” and any variations thereof are intended to cover non-exclusive inclusion. For example, a process, a method, a system, a product or an apparatus including a series of steps or units is not limited to the listed steps or units, but may further include steps or units that are not listed or steps or units that are inherently included in the process, the method, the system, the product or the apparatus.

Reference to “embodiments” herein means that particular features, structures, or characteristics described in an embodiment may be included in at least one embodiment of the present disclosure. The phrase at various sections in the specification does not necessarily refer to one same embodiment, nor separate or alternative embodiments that are mutually exclusive of other embodiments. Any ordinary skilled person in the art shall understand that, both explicitly and implicitly, the embodiments described herein may be combined with other embodiments.

The present disclosure will be described in detail by referring to drawings and embodiments.

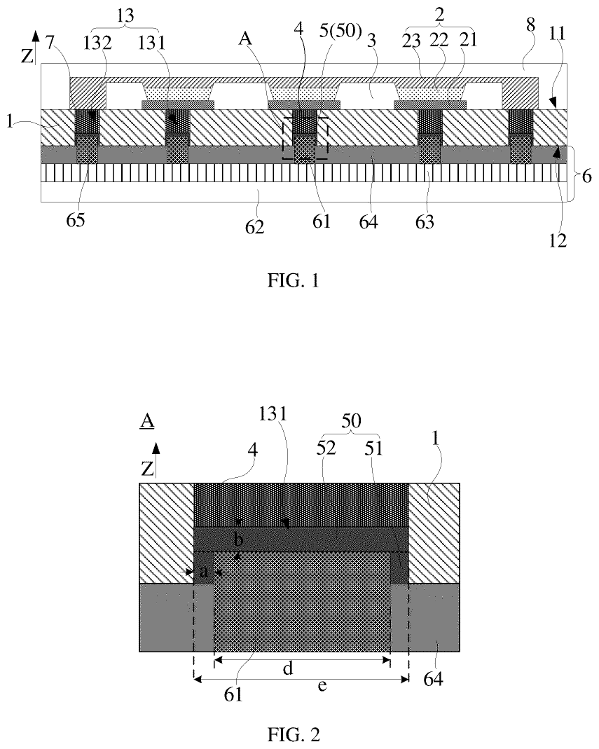

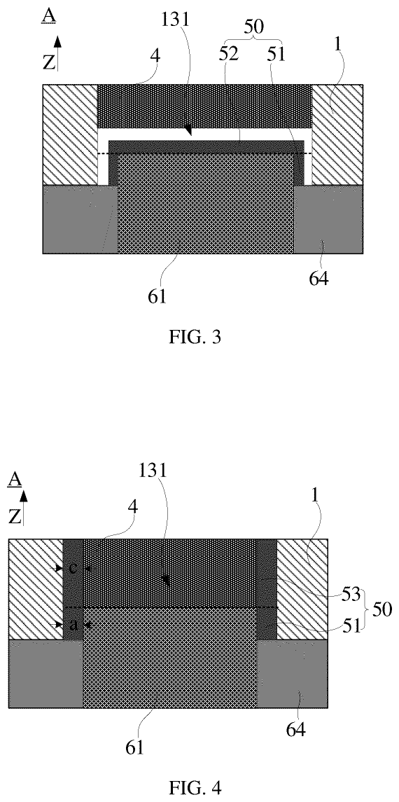

As shown in FIGS. 1 to 3, FIG. 1 is a structural schematic view of a display panel according to a first embodiment of the present disclosure; as shown in FIG. 2, FIG. 2 is an enlarged view of a portion A in the display panel shown in FIG. 1; and FIG. 3 is a structural schematic view of a conductive deformation layer shown in FIG. 2, after being deformed. The present disclosure provides a display panel, which may be an OLED display panel. The display panel may include a glass substrate 1, a plurality of light emitting units 2, a plurality of first bonding portions 4, a silicon-based driver substrate 6, and a plurality of deformation layers 5.

The glass substrate 1 may include a first surface 11 and a second surface 12 opposite to the first surface 11. The glass substrate 1 defines a plurality of conductive through holes 13 extending from the first surface 11 to the second surface 12. The plurality of conductive through holes 13 may include a plurality of first conductive through holes 131.

The plurality of light emitting units 2 may be disposed on the first surface 11 of the glass substrate 1. Each of the plurality of light emitting units 2 may include an anode electrode 21, an organic light emitting layer 22, and a cathode electrode 23 that are stacked sequentially in a direction extending away from the glass substrate 1. Specifically, the first surface 11 of the glass substrate 1 is further arranged with a pixel defining layer 3. The pixel defining layer 3 protrudes out of the glass substrate 1, and the pixel defining layer 3 and the glass substrate 1 enclose to form a plurality of pixel receiving regions (not shown in the figure). The plurality of light emitting units 2 are arranged within the plurality of pixel receiving regions. The plurality of pixel receiving regions are arranged in one-to-one correspondence with the plurality of first conductive through holes 131.

The anode electrode 21 may be arranged on a surface of the glass substrate 1 exposed through the pixel receiving regions. The pixel defining layer 3 may cover an edge of the anode electrode 21 so as to prevent the anode electrode 21 of one of the plurality of light emitting units 2 from contacting the anode electrode 21 of an adjacent one of the plurality of light emitting units 2, such that signal crosstalk may be prevented. The organic light emitting layer 22 may be disposed on a side of the anode electrode 21 away from the glass substrate 1. The cathode electrode 23 may be disposed on a side of the organic light emitting layer 22 away from the anode electrode 21 and cover the organic light emitting layer 22. Specifically, one integral cathode electrode 23 may be arranged and extending to cover the organic light emitting layer 22 of each of the plurality of light emitting units 2. The one integral cathode electrode 23 forms one integral common cathode. The one integral common cathode has a plurality of portions disposed corresponding to the plurality of light emitting units 2, such that each of the plurality of portions serves as the cathode electrode 23 for a respective one of the plurality of light emitting units 2. The anode electrode 21 and the cathode electrode 23 may transmit an anode drive signal and a cathode drive signal, respectively, to the organic light emitting layer 22 to drive the organic light emitting layer 22 to emit light.

In some embodiments, the plurality of light emitting units 2 may include light emitting units 2 that emit light in different colors, such as a red light emitting unit, a green light emitting unit, and a blue light emitting unit, such that colorful displaying may be achieved. Specifically, a light color of each light emitting unit 2 may be determined by a light color of the organic light emitting layer 22. Alternatively, in some embodiments, the plurality of light emitting units 2 may emit light in one same color, such as white, red, green, blue, or any other color, which may be determined according to the actual needs. For example, the light emitting unit 2 may emit light in white, and brightness of the light emitting unit 2 may be adjusted to achieve grayscale displaying. A color resistant layer may be arranged on top of the light emitting unit 2 to achieve the colorful displaying. For example, the plurality of light emitting units 2 may emit light in blue, and a red quantum dot layer may be arranged above a portion of the plurality of light emitting units 2, and a green quantum dot layer may be arranged above another portion of the light emitting units 2, such that the colorful displaying may be achieved.

The plurality of first bonding portions 4 may be arranged on the second surface 12 of the glass substrate 1. Each of the plurality of first bonding portions 4 may be received in a respective one of the plurality of first conductive through holes 131. Each of the plurality of bonding portions 4 may be electrically connected to the anode electrode 21 through the respective one of the plurality of first conductive through hole 13 to transmit the anode drive signal to the anode electrode 21 of a respective one of the plurality of light emitting units 2 through the respective first conductive through hole 13.

The silicon-based driver substrate 6 is arranged on a side of the second surface 12 of the glass substrate 1. The silicon-based driver substrate 6 may further include a plurality of first bonding electrodes 61. Each of the plurality of first bonding electrodes 61 may be at least partially embedded in a respective one of the plurality of first conductive through holes 131 and may be electrically connected to a respective one of the plurality of first bonding portions 4 to control a respective one of the plurality of light emitting units 2 to emit light. Specifically, each of the plurality of first bonding electrodes 61 may be spaced apart from a hole sidewall of the respective first conductive through hole 131.

Specifically, the silicon-based driver substrate 6 may further include a silicon substrate 62 and a driver circuit 63 stacked on the silicon substrate 62. The silicon substrate 62 may refer to a substrate plate having a monocrystalline silicon material as a basis. The driver circuit 63 may be electrically connected to the plurality of first bonding electrodes 61 to transmit the anode drive signal to the anode electrode 21 through the respective first bonding portion 4. Specifically, the driver circuit 63 may include an active driver circuit 63 integrated on a monocrystalline silicon substrate 62 based on a CMOS (Complementary Metal-Oxide-Semiconductor) process. Specifically, the driver circuit 63 may include a plurality of “3T1C” structures (three thin-film transistors and one capacitor) to independently control each of the plurality of light emitting units 2 to achieve high-quality displaying.

The silicon-based driver substrate 6 may further include a display control circuit (not shown) electrically connected to the driver circuit 63. The display control circuit may control, through the driver circuit 63, the plurality of light emitting units 2 to display contents. The display control circuit may be an integrated circuit (IC) integrated on the silicon-based driver substrate 6.

By arranging the plurality of light emitting units 2 and the plurality of first bonding portions 4 respectively on two opposite surfaces of the glass substrate 1, each of the plurality of first bonding portions 4 may be electrically connected, through the respective one of the plurality of first conductive through holes 131, to the anode electrode 21 of the respective one of the plurality of light emitting units 2. In this way, the plurality of light emitting units 2 may be electrically coupled with the silicon-based driver substrate 6, such that the silicon-based driver substrate 6 may drive the plurality of light emitting units 2 to emit light. Therefore, the plurality of light emitting units 2 may be not be directly prepared on the silicon-based driver substrate 6, damages to the pixel driver circuit 63, which may be caused by directly preparing the plurality of light emitting units 2 on the silicon-based driver substrate 6, may be avoided, and the product yield may not be reduced. In addition, compared to through holes in silicon material, through holes in glass may provide excellent high-frequency electrical characteristics, have low costs, may be achieved by performing simple processes, and may be highly mechanically stable.

As shown in FIGS. 2 and 3, each of the plurality of deformation layers 5 may be at least partially disposed between a respective one of the plurality of first bonding electrodes 61 and the hole sidewall of the respective first conductive through hole 131. The hole sidewall of each first conductive through hole 131 in the glass substrate 1 may be fixedly connected to the respective first bonding electrode 61 through the respective deformation layer 5. When a temperature of the deformation layer 5 is lower than a predetermined temperature, the deformation layer 5 may be deformed, enabling a thickness of the deformation layer 5 to be smaller than a spacing between the first bonding electrode 61 and the hole sidewall of the first conductive through hole 131.

The thickness of the deformation layer 5 being less than the spacing between the first bonding electrode 61 and the hole sidewall of the first conductive through hole 131 may refer to that the deformation layer 5, after being deformed, is separated from the hole sidewall of the first conductive through hole 131 and attached to the first bonding electrode 61; or the deformation layer 5, after being deformed, is separated from the first bonding electrode 61 and attached to the hole sidewall of the first conductive through hole 131; or the deformation layer 5, after being deformed, is separated from both the first bonding electrode 61 and the hole sidewall of the first conductive through hole 131.

By filling a gap between the first bonding electrode 61 and the hole sidewall of the first conductive through hole 131 with the deformation layer 5, when the glass substrate 1 and the silicon-based driver substrate 6 need to be peeled apart from each other due to a process problem occurring during preparing the display panel, the deformation layer 5 may be cooled to be deformed. When the temperature of the deformation layer 5 is lower than the predetermined temperature, the deformation layer 5 may be deformed, enabling the thickness of the deformation layer 5 that fills the gap to be reduced, such that the first bonding electrode 61 may be separated from the hole sidewall of the first conductive through hole 131. Therefore, the glass substrate 1 and the silicon-based driver substrate 6 may be peeled apart from each other more easily, and the peeling efficiency may be effectively improved.

Following embodiments of the present disclosure will be explained and illustrated based on examples where the deformation layer 5, after being deformed, is separated from the hole sidewall of the first conductive through hole 131 and is attached to the first bonding electrode 61.

As shown in FIG. 2, in an embodiment, the deformation layer 5 may be a conductive deformation layer 50. The conductive deformation layer 50 may include a first conductive deformation layer 51 disposed between the first bonding electrode 61 and the hole sidewall of the first conductive through hole 131 and a second conductive deformation layer 52 disposed between the first bonding electrode 61 and the first bonding portion 4. The first conductive deformation layer 51 and the second conductive deformation layer 52 may be integrally formed as a one-piece structure. The first bonding electrode 61 may be fixedly connected to the glass substrate 1 through the first conductive deformation layer 51 and may be fixedly connected to the first bonding portion 4 through the second conductive deformation layer 52. In this way, the silicon-based driver substrate 6 may be bonded to the glass substrate 1. The first bonding electrode 61 may further be electrically connected to the first bonding portion 4 through the second conductive deformation layer 52 to transmit an anode drive signal to the anode electrode 21.

As shown in FIG. 3, when the glass substrate 1 needs to be peeled off from the silicon-based driver substrate 6, the display panel may be cooled down by a cooling device, so as to peel the first bonding electrode 61 off from the glass substrate 1. Specifically, when a temperature of the first conductive deformation layer 51 is lower than the predetermined temperature, the first conductive deformation layer 51 may be deformed and may be separated from the hole sidewall of the first conductive through hole 131. When a temperature of the second conductive deformation layer 52 is lower than the predetermined temperature, the second conductive deformation layer 52 may be deformed and may be separated from the first bonding portion 4. In this way, the first bonding electrode 61 may be separated from both the glass substrate 1 and the first bonding portion 4. Therefore, the glass substrate 1 and the silicon-based driver substrate 6 may be peeled apart from each other more easily, and the peeling efficiency may be effectively improved.

Specifically, the first conductive deformation layer 51, after being deformed, may be separated from the hole sidewall of the first conductive through hole 131 and attached to a side wall of the first bonding electrode 61. The second electrically conductive deformation layer 52, after being deformed, may be separated from the first bonding portion 4 and attached to a top wall of the first bonding electrode 61.

In an embodiment, a thickness a of the first conductive deformation layer 51 may be less than or equal to a thickness b of the second conductive deformation layer 52. By increasing the thickness of the second conductive deformation layer 52, a deformation distance of the second conductive deformation layer 52 between the first bonding electrode 61 and the first bonding portion 4 may be greater when the second conductive deformation layer 52 is cooled down, such that the first bonding electrode 61 and the first bonding portion 4 may be separated from each other more easily. The thickness a of the first conductive deformation layer 51 may be a size of the first conductive deformation layer 51 in a direction perpendicular to a sidewall surface of the first bonding electrode 61. The thickness b of the second conductive deformation layer 52 may be a size of the second conductive deformation layer 52 in a direction perpendicular to the silicon-based driver substrate 6.

In an embodiment, the conductive deformation layer 50 may be a graphene silicone rubber layer. The graphene silicone rubber may be a composite material that combines graphene and silicone rubber, and may have ideal electrical conductivity, mechanical performance, thermal stability, and weather resistance. Specifically, the predetermined temperature may be higher than minus 35° C. less than minus 25° C. It can be understood that, by setting the predetermined temperature to be lower than minus 25° C., the conductive deformation layer 50 may not be deformed at room temperature, such that normal operation of the display panel may not be affected. By setting the predetermined temperature to be higher than minus 35° C., energy consumption may be reduced, and costs may be saved. Specifically, the predetermined temperature may be in any value of: −35° C., −32° C., −30° C., −28° C., or −25° C.

As shown in FIG. 2, a sum of a width d of the first bonding electrode 61 and thicknesses a of two first conductive deformation layers 51 respectively disposed on two sides of the first bonding electrode 61 along a width direction of the first bonding electrode 61 may be less than or equal to a width e of the first conductive through hole 131. In this way, it is ensured that the first bonding electrode 61 covered by the conductive deformation layer may be embedded into the first conductive through hole 131. To be noted that, the sum of the width d of the first bonding electrode 61 and the thicknesses a of the two first conductive deformation layers 51 respectively disposed on two sides of the first bonding electrode 61 may be only slightly less than the width e of the first conductive through hole 131. The gap between the conductive deformation layer 50 and the first conductive through hole 131 may be prevented from being excessively large, and therefore, bonding between the glass substrate 1 and the silicon-based driver substrate 6 may not be affected.

Specifically, the thickness of the conductive deformation layer 50 may be greater than or equal to one-sixth of the width d of the first bonding electrode 61 and may be less than or equal to one-fourth of the width of the first bonding electrode 61. In this way, the conductive deformation layer 50 may not be excessively thick, and therefore, a large resistance may be avoided, and signal transmission may not be affected. Meanwhile, the conductive deformation layer 50 may not be excessively thin, therefore, the amount of generated deformation may not be excessively small, and separation of the first bonding electrode 61 from the glass substrate 1 may not be affected. In some embodiments, the sum of the width d of the first bonding electrode 61 and the thicknesses a of the two first conductive deformation layers 51 respectively disposed on two sides of the first bonding electrode 61 may be equal to one-fifth of the width e of the first conductive through hole 131.

Specifically, in an example, the width e of the first conductive through hole 131 may be 1 μm, the thickness of the conductive deformation layer 50 may be 0.1 μm to 0.2 μm, and the width d of the first bonding electrode 61 may be 0.5 μm to 0.8 μm.

In an embodiment, a surface of the first bonding electrode 61 may be roughened, enabling a surface roughness of the first bonding electrode 61 to be greater than or equal to 0.2 μm and less than or equal to 0.4 μm, such that an attachment area of the conductive deforming layer 50 on the surface of the first bonding electrode 61 may be increased, and adhesion strength between the conductive deforming layer 50 and the first bonding electrode 61 may be improved. Specifically, the surface roughness of the first bonding electrode 61 may be in any value of 0.2 μm, 0.25 μm, 0.3 μm, 0.35 μm, or 0.4 μm.

The silicon-based driver substrate 6 may further include a protection layer 64 disposed on a side near the glass substrate 1. At least a portion of the first bonding electrode 61 may be embedded in the protection layer 64. The protection layer 64 may be configured to protect the driver circuit 63 from being corroded by external water vapor. A material of the protection layer 64 may be an inorganic insulating material such as silicon dioxide, silicon nitride, or silicon nitride oxide. The first bonding electrode 61 may protrude from the protection layer 64, and the conductive deformation layer 50 may cover a surface of a portion of the first bonding electrode 61 protruding out of the protection layer 64.

As shown in FIG. 1, in an embodiment, the plurality of conductive through holes 13 may further include a plurality of second conductive through holes 132 that are located at a circumferential periphery of the plurality of first conductive through holes 131. The display panel may further include a plurality of second bonding portions 7. Each of the plurality of second bonding portions 7 may be at least partially received in a respective one of the plurality of second conductive through holes 132. Each of the plurality of second bonding portions 7 may be electrically connected to the cathode electrode 23 via the respective second conductive through hole 13 to transmit the cathode drive signal to the cathode electrode 23 of the respective light emitting unit 2 via the respective second conductive through hole 13. The silicon-based driver substrate 6 may further include a plurality of second bonding electrodes 65. Each of the plurality of second bonding electrodes 65 may be aligned and bonded with a respective one of the plurality of second bonding portions 7. The silicon-based driver substrate 6 may transmit the cathode drive signal to the cathode electrode 23 through the second bonding electrode 65 and the second bonding portion 7 to control the light emitting unit 2 to emit light.

As shown in FIG. 1, in an embodiment, the glass substrate 1 is further arranged with an encapsulation layer 8 to protect the plurality of light emitting units 2 on the glass substrate 1, isolating the external water and oxygen and avoiding failure of the light emitting units 2 caused by invasion of the water and the oxygen. Specifically, the encapsulation layer 8 may cover a side surface of the cathode electrode 23 away from the anode electrode 21 and may lap over a portion of a surface of the glass substrate 1 that is not covered by the light emitting units 2.

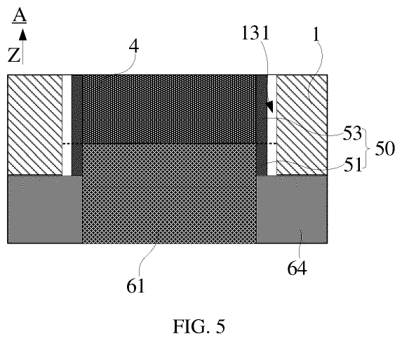

As shown in FIGS. 4 and 5, FIG. 4 is an enlarged view of the portion A in the display panel according to a second embodiment of the present disclosure; and FIG. 5 is a structural schematic view of the conductive deformation layer shown in FIG. 4, after being deformed. A structure of the display panel provided in the second embodiment may be substantially the same as that of the display panel provided in the first embodiment. In the second embodiment, the first bonding portion 4 may be received in the first conductive through hole 131 and may be spaced apart from the hole sidewall of the first conductive through hole 131. The plurality of first bonding portions 4 and the plurality of first bonding electrodes 61 are bonded to each other in a one-to-one correspondence manner. By arranging the plurality of first bonding portions 4 to be directly bonded to the plurality of first bonding electrodes 61, resistance between the first bonding electrodes 61 and the first bonding portions 4 may be reduced, and signal transmission between the first bonding electrodes 61 and the first bonding portions 4 may be ensured.

The deformation layer 5 may be the conductive deformation layer 50. The conductive deformation layer 50 may include the first conductive deformation layer 51 disposed between the first bonding electrode 61 and the hole sidewall of the first conductive through hole 131 and a third conductive deformation layer 53 disposed between the first bonding portion 4 and the hole sidewall of the first conductive through hole 131. By arranging the third conductive deformation layer 53 between the first bonding portion 4 and the hole sidewall of the first conductive through hole 131, when a temperature of the third conductive deformation layer 53 is lower than the predetermined temperature, the third conductive deformation layer 53 may be deformed, enabling a thickness of the third conductive deformation layer 53 to be decreased. In this way, the first bonding portion 4 and the hole sidewall of the first conductive through hole 131 may be separated from each other, and the first bonding portion 4 may maintain being bonded with the first bonding electrode 61.

As shown in FIG. 5, when the glass substrate 1 needs to be peeled off from the silicon-based driver substrate 6, the display panel may be cooled down by the cooling device, such that the first bonding electrode 61 may be peeled off from the glass substrate 1. Specifically, when the temperature of the first conductive deformation layer 51 is lower than the predetermined temperature, the first conductive deformation layer 51 may be deformed and separated from the hole sidewall of the first conductive through hole 131. When the temperature of the third conductive deformation layer 53 is lower than the predetermined temperature, the third conductive deformation layer 53 may be deformed and separated from the hle sidewall of the first conductive through hole 131. In this way, the first bonding portion 4 and the first bonding electrode 61 may be simultaneously separated from the hole sidewall of the first conductive through hole 131 of the glass substrate 1. Therefore, the glass substrate 1 and the silicon-based driver substrate 6 may be peeled apart from each other more easily, and the peeling efficiency may be effectively improved.

Specifically, the first conductive deformation layer 51, after being deformed, may be separated from the hole sidewall of the first conductive through hole 131 and attached to the side wall of the first bonding electrode 61. The second conductive deformation layer 52, after being deformed, may be separated from the hole sidewall of the first conductive through hole 131 and attached to the sidewall of the first bonding portion 4. The thickness a of the first conductive deformation layer 51 may be equal to a thickness c of the third conductive deformation layer 53.

The present disclosure provides a display panel and a method of manufacturing the display panel. The display panel may include the glass substrate 1, the plurality of light emitting units 2, the plurality of first bonding portions 4, the silicon-based driver substrate 6, and the plurality of deformation layers 5. By arranging the light emitting units 2 and the first bonding portions 4 respectively on two opposite surfaces of the glass substrate 1, each of the plurality of first bonding portions 4 may be electrically connected, through the respective first conductive through hole 131, to the anode electrode 21 of the respective light emitting unit 2 to electrically couple the light emitting unit 2 with the silicon-based driver substrate 6, such that the silicon-based driver substrate 6 may drive the plurality of light emitting units 2 to emit light. In this way, damages to a pixel driver circuit 63, caused by directly preparing the light emitting units 2 on the silicon-based driver substrate 6, may be avoided, and therefore, a product yield may not be affected. Further, by filling the gap between the first bonding electrode 61 and the hole sidewall of the first conductive through hole 131 with the deformation layer 5, when the glass substrate 1 and the silicon-based driver substrate 6 need to be peeled apart from each other due to a process problem occurring during preparing the display panel, the deformation layer 5 may be cooled down, enabling the temperature of the deformation layer 5 to be lower than the predetermined temperature to be deformed, such that the thickness of the deformation layer 5 that fills the gap may be reduced. In this way, the first bonding electrode 61 may separate from the hole sidewall of the first conductive through hole 131, and therefore, the glass substrate 1 and the silicon-based driver substrate 6 may be peeled apart from each other more easily, and a peeling efficiency may be effectively improved.

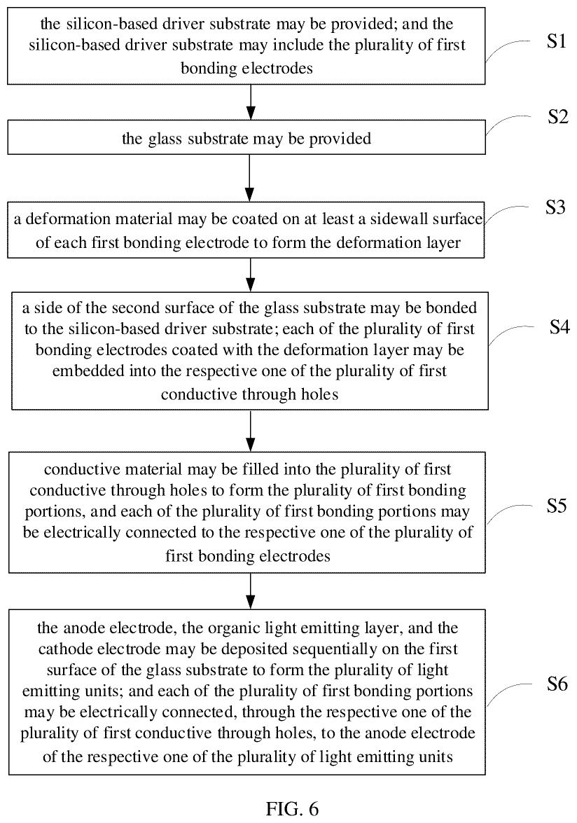

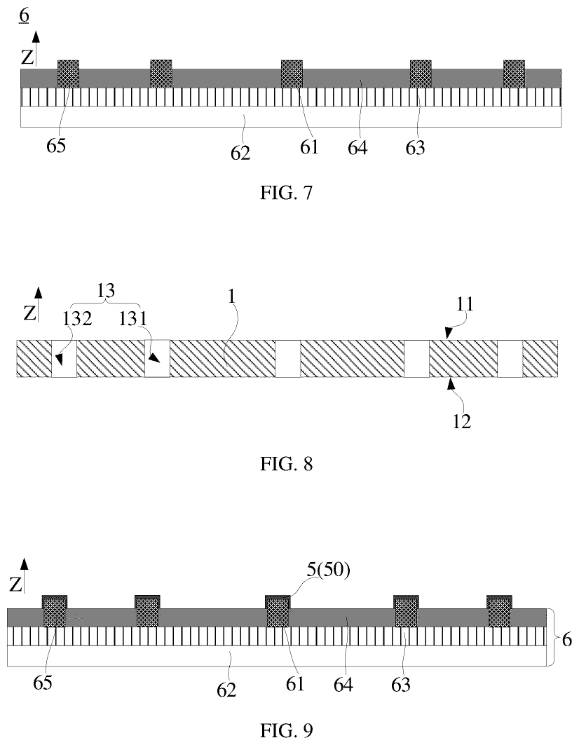

As shown in FIGS. 6-FIG. 12, FIG. 6 is a flow chart of the method of manufacturing the display panel according to an embodiment of the present disclosure; FIG. 7 is a structural schematic view of a component in an operation S1 shown in FIG. 6; FIG. 8 is a structural schematic view of a component in an operation S2 shown in FIG. 6; FIG. 9 is a structural schematic view of a component in an operation S3 shown in FIG. 6; IG. 10 is a structural schematic view of a component in an operation S4 shown in FIG. 6; FIG. 11 is a structural schematic view of a component in an operation S5 shown in FIG. 6; and FIG. 12 is a structural schematic view of a component in an operation S6 shown in FIG. 6. The present disclosure further provides the method of manufacturing the display panel as described in any of the above embodiments. As shown in FIG. 6, the method may include following operations.

In an operation S1, the silicon-based driver substrate may be provided; and the silicon-based driver substrate may include the plurality of first bonding electrodes.

Specifically, as shown in FIG. 7, the silicon substrate 62 may be prepared based on a monocrystalline silicon material, and the driver circuit 63 may be prepared on the silicon substrate 62. By preparing the driver circuit 63 on the silicon substrate 62, the plurality of light emitting units 2 may be prepared separately from the silicon-based driver substrate 6. In this way, a production efficiency may be improved. Moreover, by taking the silicon substrate 62 as the substrate for the silicon-based driver substrate 6, advantages of the silicon-based driver substrate 6 may be retained.

A conductive material may be deposited on a side surface of the driver circuit 63 away from the silicon substrate 62 and may be patterned to form the plurality of first bonding electrodes 61 and the plurality of second bonding electrodes 65. Each of the plurality of first bonding electrodes 61 and each of the plurality of second bonding electrodes 65 may be electrically connected to the driver circuit 63. In this way, the driver circuit 63 may transmit the anode drive signal through the first bonding electrodes 61 and may transmit the cathode drive signals through the second bonding electrodes 65.

An insulating material may be deposited on the side surface of the driver circuit 63 away from the silicon substrate 62 to form the protection layer 64 to protect the driver circuit 63. A plurality of through holes may be defined in the protection layer 64 at positions corresponding to the plurality of first bonding electrodes 61 and the plurality of second bonding electrodes 65 to enable the plurality of first bonding electrodes 61 and the plurality of second bonding electrodes 65 to be exposed through the plurality of through holes. That is, the plurality of first bonding electrodes 61 and the plurality of second bonding electrodes 65 may be embedded in the first through holes of the protection layer 64. The plurality of first bonding electrodes 61 and the plurality of second bonding electrodes 65 may protrude from the surface of the protection layer 64 away from the silicon substrate 62.

In an operation S2, the glass substrate may be provided.

Specifically, as shown in FIG. 8, the glass substrate 1 may include the first surface 11 and the second surface 12 opposite to the first surface 11. Specifically, a surface located on a light-out side of the display panel may be the first surface 11, and a surface opposite to the first surface may be the second surface 12. The glass substrate 1 may define the plurality of conductive through holes 13 extending from the first surface 11 to the second surface 12. In an implementation, a laser-induced etching technique may be applied to form the plurality of conductive through holes in the glass substrate 1. The plurality of conductive through holes 13 may include the plurality of first conductive through holes 131 and the plurality of second conductive through holes 132.

Specifically, positions on the glass substrate 1 where the plurality of conductive through holes are to be defined may be irradiated by a laser to form modified regions. An etching solution may be applied to the modified regions for etching to form the plurality of conductive through holes 13. By using the glass substrate 1 as the substrate, compared to the silicon substrate 62, the glass substrate 1 may have better insulating performance, and therefore, an oxidized insulating layer does not need to be formed on a hole wall of each conductive through hole 13, and a specialized holding technology for thin wafers may not be applied. Therefore, costs are reduced. Furthermore, due to the ideal insulating performance of the glass substrate 1, electromagnetic coupling effects may not be generated during transmitting signals. Therefore, an insertion loss of signals, signal crosstalk and other problems may be effectively reduced, ensuring integrity of signals. In addition, compared to through holes in silicon material, through holes in glass may provide excellent high-frequency electrical characteristics, have low costs, may be achieved by performing simple processes, and may be highly mechanically stable.

In an operation S3, a deformation material may be coated on at least a sidewall surface of each first bonding electrode to form the deformation layer.

Specifically, as shown in FIG. 9, the deformation material may be at least coated on a side wall of the portion of the first bonding electrode 61 protruding out of the protection layer 64 to form the deformation layer 5. Specifically, the deformation layer may be the conductive deformation layer, the deformation material may be a conductive deformation material, which may be graphene silicone rubber. In an implementation, the operation S3 may specifically include following operations.

In an operation S31, the conductive deformation material may be coated on the sidewall surface of each first bonding electrode to form the first conductive deformation layer; and the conductive deformation material may be coated on a top wall surface of each second bonding electrode to form the second conductive deformation layer.

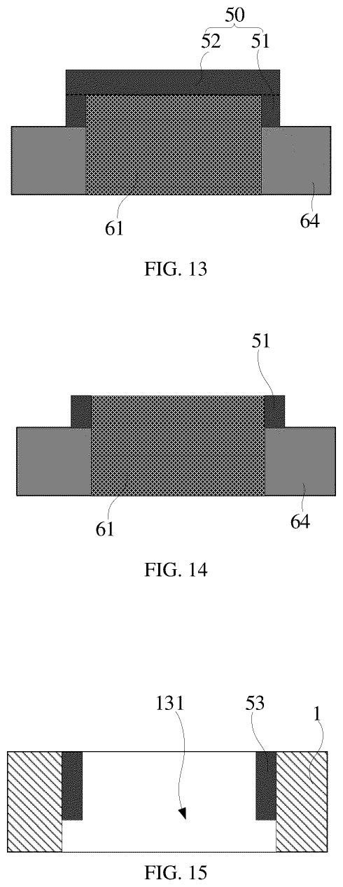

As shown in FIG. 13, FIG. 13 is a structural schematic view of a component in the operation S31 shown in FIG. 6. Firstly, the surface of the portion of the first bonding electrode 61 protruding out of the protection layer 64 may be roughened to increase roughness of the surface of the first bonding electrode 61 to increase an adhesion area of the first conductive deformation layer 51 and the second conductive deformation layer 52 coating on the surface of the first bonding electrode 61. In this way, adhesion strengthen of the first conductive deformation layer 51 and the second conductive deformation layer 52 adhered to the first bonding electrode 61 may be improved.

Subsequently, the conductive deformation material may be coated on the sidewall surface and the top wall surface of the portion of the first bonding electrode 61 protruding out of the protection layer 64 to form the first conductive deformation layer 51 and the second conductive deformation layer 52. The thickness of the second conductive deformation layer 52 may be greater than or equal to the thickness of the first conductive deformation layer 51. The thickness a of the first conductive deformation layer 51 may be the size of the first conductive deformation layer 51 in the direction perpendicular to the sidewall surface of the first bonding electrode 61. The thickness b of the second conductive deformation layer 52 may be the size of the second conductive deformation layer 52 in the direction perpendicular to the silicon-based driver substrate 6.

Alternatively, in other embodiments, the operation S3 specifically may further include following operations.

In an operation S31A, the conductive deformation material may be coated on the sidewall surface of each first bonding electrode to form the first conductive deformation layer.

As shown in FIG. 14, FIG. 14 is a structural schematic view of a component in the operation S31A shown in FIG. 6. Firstly, the sidewall surface of the portion of the first bonding electrode 61 protruding out of the protection layer 64 may be roughened to increase the roughness of the sidewall surface of the first bonding electrode 61, such that the adherence area of the first conductive deformation layer 51 adhered on the sidewall surface of the first bonding electrode 61 may be increased, and the adhesion strength of the first conductive deformation layer 51 adhered to the first bonding electrode may be improved.

Subsequently, the conductive deformation material may be coated on the sidewall surface of the portion of the first bonding electrode 61 protruding out of the protection layer 64 to form the first conductive deformation layer 51.

In an operation S32A, the conductive deformation material may be deposited on the sidewall surface of the first conductive through hole, and a portion of the conductive material located near the second surface may be removed, such that the third conductive deformation layer may be formed.

As shown in FIG. 15, FIG. 15 is a structural schematic view of a component in the operation S32A shown in FIG. 6. The conductive deformation material may be deposited on the sidewall surface of the first conductive through hole 131, and the portion of the conductive material near the second surface 12 may be removed, such that the third conductive deformation layer 53 may be formed.

Subsequently, an inner sidewall of the third conductive deformation layer 53 may be roughened to increase surface roughness of the third conductive deformation layer 53, such that an adhesion area between the first bonding portion 4 and the third conductive deformation layer 53, which will be subsequently formed, may be increased; and adhesive strength between the first bonding portion 4 and the third conductive deformation layer 53 may be improved.

Of course, the inner sidewall of the first conductive through hole 131 may be firstly roughened, and subsequently, the third conductive deformation layer 53 may be formed by depositing the conductive deformation material on the sidewall surface of the first conductive through hole 131. In this way, the adhesion strength between the third conductive deformation layer 53 and the inner sidewall of the first conductive through hole 131 may be improved.

In an operation S4, a side of the second surface of the glass substrate may be bonded to the silicon-based driver substrate; each of the plurality of first bonding electrodes coated with the deformation layer may be embedded into the respective one of the plurality of first conductive through holes.

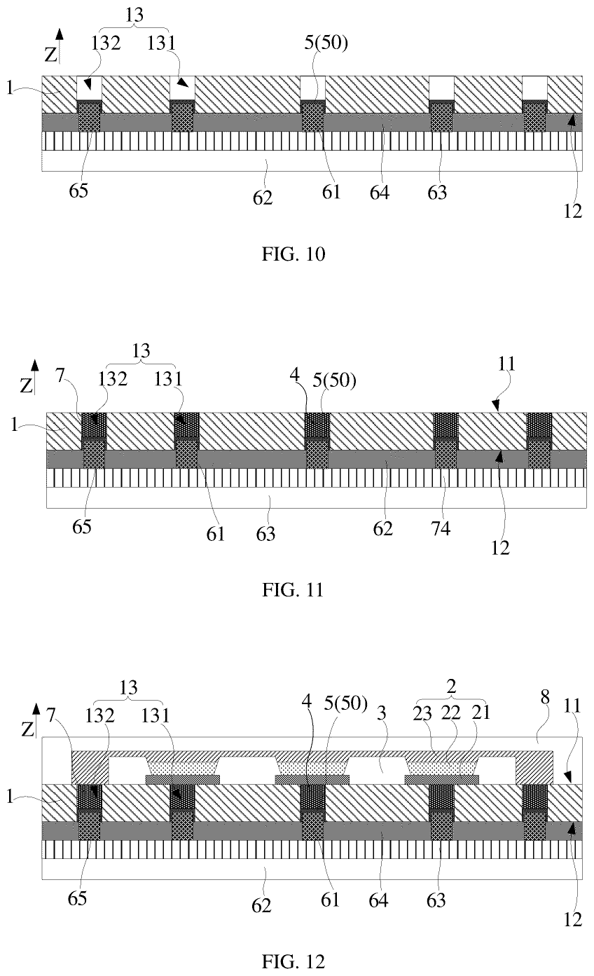

Specifically, as shown in FIG. 10, a side of the silicon-based driver substrate 6 having the first bonding electrodes 61 may be bonded to the side of the second surface 12 of the glass substrate 1. The portion of each first bonding electrode 61 protruding out of the protection layer 64 and the conductive deformation layer 50 coated on the surface of the portion of the first bonding electrode 61 may be embedded in the respective first conductive through hole 131. In this way, the driver circuit 63 may transmit the anode drive signals through the first conductive through hole 131. Each second bonding electrode 65 may be embedded in the respective second conductive through hole 132, such that the driver circuit 63 may transmit the cathode drive signals through the second conductive through hole 132.

In an operation S5, conductive material may be filled into the plurality of first conductive through holes to form the plurality of first bonding portions, and each of the plurality of first bonding portions may be electrically connected to the respective one of the plurality of first bonding electrodes.

Specifically, as shown in FIG. 11, the conductive material may be deposited, from a side of the first surface 11 of the glass substrate 1, into the plurality of first conductive through holes 131. The conductive material in the first conductive through holes 131 may be cured to form the plurality of first bonding portions 4. In this way, each first bonding portion 4 may be electrically connected to the respective first bonding electrode 61 via the conductive deformation layer 50. At the same time, the conductive material may be deposited into the plurality of second conductive through holes 132 and cured to form the plurality of second bonding portions 7. In this way, each of the plurality of second bonding portions 7 may be electrically connected to the respective one of the plurality of second bonding electrodes 65.

In an operation S6, the anode electrode, the organic light emitting layer, and the cathode electrode may be deposited sequentially on the first surface of the glass substrate to form the plurality of light emitting units; and each of the plurality of first bonding portions may be electrically connected, through the respective one of the plurality of first conductive through holes, to the anode electrode of the respective one of the plurality of light emitting units.

Specifically, as shown in FIG. 12, the conductive material may be deposited on the first surface 11 of the glass substrate 1 may be patterned to form a plurality of anode electrodes 21 that are spaced apart from each other. Each anode electrode 21 may completely cover the respective first conductive through hole 131, such that the anode electrode 21 may be electrically connect to the respective first bonding portion 4 through the respective first conductive through hole 131.

The pixel defining layers 3, the organic light emitting layers 22, and the cathode electrodes 23 may be sequentially prepared on a side of the plurality of anode electrodes 21 away from the glass substrate 1 to form the plurality of light emitting units 2. The pixel defining layers 3 may formed by patterning photoresist on the first surface 11 of the glass substrate 1; or by patterning an inorganic material film layer. A specific preparing method may be determined according to practical demands. The pixel defining layers 3 may protrude from the glass substrate 1 and form a plurality of pixel receiving regions. The pixel defining layer 3 may cover edges of the anode electrodes 21, ensuring that adjacent anode electrodes 21 may not be in contact with each other. A partial surface of each anode electrode 21 may be exposed through the pixel receiving regions, such that the organic light emitting layers 22 may be prepared on surfaces of the anode electrodes 21 disposed in the pixel receiving regions.

Different light emitting layer materials may be used for evaporation performed on the surfaces of a plurality of anode electrodes 21 to form a plurality of organic light emitting layers 22 having different emitted light colors, such as a red light-emitting layer, a green light-emitting layer, and a blue light-emitting layer. Alternatively, a white light-emitting layer material may be used for evaporation to form a white light-emitting layer, and subsequently, color filtering layers may be prepared to achieve color display.

In an implementation, a cathode material may be deposited, by evaporation or sputtering, on the side of the organic light emitting layers 22 away from the glass substrate 1 to form the cathode electrode 23. Specifically, the cathode material may be deposited on the plurality of organic light emitting layers 22 and the plurality of pixel defining layers 3 and may be extended to be deposited on the second conductive through holes 132 to further contact the second bonding portions 7 through the second conductive through holes 132 to form electrical connection. In this way, one integral planar cathode electrode 23 may be formed, such that homogeneity of the cathode drive signal may be improved, and a voltage drop may be reduced.

The present disclosure provides a method of manufacturing the display panel. The silicon-based driver substrate 6 may be firstly provided. The silicon-based driver substrate 6 includes the plurality of first bonding electrodes 61. The glass substrate 1 may then be provided. The glass substrate 1 includes the first surface 11 and the second surface 12 opposite to the first surface 11. The glass substrate 1 may have the plurality of conductive through holes 13 extending from the first surface 11 to the second surface 12. The plurality of conductive through holes 13 includes the plurality of first conductive through holes 131. The deformation material may be coated on at least the sidewall surface of each first bonding electrode 61 to form the deformation layer 5. The second surface 12 of the glass substrate 1 may be bonded to the silicon-based driver substrate 6. The plurality of first bonding electrodes 61 coated with the deformation layers 5 may be embedded in the first conductive through holes 131. The conductive material may be filled into the plurality of first conductive through holes 131 to form the plurality of first bonding portions 4. The plurality of first bonding portions 4 may be electrically connected with the plurality of first bonding electrodes 61 correspondingly. The anode electrodes 21, the organic light emitting layers 22, and the cathode electrode 23 may be deposited sequentially on the first surface 11 of the glass substrate 1 to form the plurality of light emitting units 2. The plurality of first bonding portions 4 may be electrically connected to the anode electrodes 21 through the first conductive through holes 131 correspondingly. According to the above method, damage to the pixel driver circuit 63, caused by directly preparing the light emitting units 2 on the silicon-based driver substrate 6, may be avoided, and the peeling efficiency may be effectively improved.

The above is only an implementation of the present disclosure, and is not intended to limit the scope of the present disclosure. Any equivalent structure or equivalent process transformation performed based on the contents of the specification and the accompanying drawings of the present disclosure, applied directly or indirectly in other related technical fields, shall be equivalently included in the scope of the present disclosure.

What is claimed is:

1. A display panel, comprising:
a glass substrate, comprising a first surface and a second surface opposite to the first surface, wherein the glass substrate defines a plurality of conductive through holes extending from the first surface to the second surface; the plurality of the conductive through holes comprises a plurality of first conductive through holes;
a plurality of light emitting units, arranged on the first surface of the glass substrate; wherein each of the plurality of light emitting units comprises an anode electrode, an organic light emitting layer, and a cathode electrode that are stacked sequentially in a direction away from the glass substrate;
a plurality of first bonding portions, wherein each of the plurality of first bonding portions is received in a respective one of the plurality of first conductive through holes; each of the plurality of first bonding portions is electrically connected, through the respective first conductive through hole, to the anode electrode of a respective one of the plurality of light emitting units;
a silicon-based driver substrate, arranged at a side of the second surface of the glass substrate and comprising a plurality of first bonding electrodes; wherein each of the plurality of first bonding electrodes; is at least partially embedded in a respective one of the plurality of first conductive through holes and is electrically connected to a respective one of the plurality of first bonding portions; each of the plurality of first bonding electrodes is spaced apart manner from a hole sidewall of the respective first conductive through hole;
a plurality of deformation layers, wherein each of the plurality of deformation layers is at least partially disposed between a respective one of the plurality of first bonding electrodes and the hole sidewall of the respective first conductive through hole; in response to a temperature of the deformation layer being lower than a predetermined temperature, the deformation layer is deformed, and a thickness of the deformation layer is less than a spacing between the first bonding electrode and the hole sidewall of the first conductive through hole.

2. The display panel according to claim 1, wherein,
each of the plurality of deformation layers is a conductive deformation layer; the conductive deformation layer comprises: a first conductive deformation layer, disposed between the first bonding electrode and the hole sidewall of the first conductive through hole; and a second conductive deformation layer, disposed between the first bonding electrode and the first bonding portion;
in response to a temperature of the first conductive deformation layer being lower than the predetermined temperature, the first conductive deformation layer is deformed and is separated from the hole sidewall of the first conductive through hole; and
in response to a temperature of the second conductive deformation layer being lower than the predetermined temperature, the second conductive deformation layer is deformed and is separated from the first bonding portion.

3. The display panel according to claim 2, wherein the thickness of the first conductive deformation layer is less than or equal to the thickness of the second conductive deformation layer.

4. The display panel according to claim 3, wherein a deforming distance generated by the second conductive deformation layer when the temperature of the second conductive deformation layer is lower than the predetermined temperature is greater than a deforming distance generated by the first conductive deformation layer when the temperature of the first conductive deformation layer is lower than the predetermined temperature.

5. The display panel according to claim 1, wherein,
each of the plurality of first bonding portions is received in the respective one of the plurality of first conductive through holes and spaced apart from the hole sidewall of the respective first conductive through hole; the plurality of first bonding portions are correspondingly bonded to the plurality of first bonding electrodes in a one-to-one correspondence manner;
each of the plurality of deformation layers is a conductive deformation layer; the conductive deformation layer comprises: a first conductive deformation layer disposed between the first bonding electrode and the hole sidewall of the first conductive through hole, and a third conductive deformation layer disposed between the first bonding portion and the hole sidewall of the first conductive through hole;
in response to a temperature of the first conductive deformation layer being lower than the predetermined temperature, the first conductive deformation layer is deformed and is separated from the hole sidewall of the first conductive through hole;
in response to a temperature of the third conductive deformation layer being lower than the predetermined temperature, the third conductive deformation layer is deformed and is separated from the hole sidewall of the first conductive through hole.

6. The display panel according to claim 5, wherein, a thickness of the first conductive deformation layer is equal to a thickness of the third conductive deformation layer.

7. The display panel according to claim 1, wherein, in response to the temperature of the deformation layer being lower than the predetermined temperature, the deformation layer is deformed and is separated from at least one of the hole sidewall of the first conductive through hole and the first bonding electrode.

8. The display panel according to claim 7, wherein, in response to the temperature of the deformation layer being lower than the predetermined temperature, the deformation layer is deformed and is separated from the hole sidewall of the first conductive through hole and is attached to the first bonding electrode.

9. The display panel according to claim 7, wherein, in response to the temperature of the deformation layer being lower than the predetermined temperature, the deformation layer is deformed and is separated from the first bonding electrode and is attached to the hole sidewall of the first conductive through hole.

10. The display panel according to claim 7, wherein, in response to the temperature of the deformation layer being lower than the predetermined temperature, the deformation layer is deformed and is separated from both the first bonding electrode and the hole sidewall of the first conductive through hole.

11. The display panel according to claim 2, wherein the conductive deformation layer is a graphene silicone rubber layer; and the predetermined temperature is higher than −35° C. and lower than −25° C.

12. The display panel according to claim 2, wherein the thickness of the conductive deformation layer is greater than or equal to one-sixth of a width of the respective first bonding electrode and is less than or equal to one-fourth of the width of the respective first bonding electrode.

13. The display panel according to claim 2, wherein a sum of the width of the first bonding electrode and thicknesses of two first conductive deformation layers respectively disposed on two sides of the first bonding electrode along a width direction of the first bonding electrode is less than or equal to a width of the first conductive through hole.

14. The display panel according to claim 13, wherein the sum of the width of the first bonding electrode and thicknesses of two first conductive deformation layers respectively disposed on two sides of the first bonding electrode is equal to one-fifth of the width of the first conductive through hole.

15. The display panel according to claim 1, wherein, a surface roughness of the first bonding electrode is greater than or equal to 0.2 μm and less than or equal to 0.4 μm.

16. The display panel according to claim 2, wherein the silicon-based driver substrate further comprises a protection layer arranged on a surface near the glass substrate; a portion of each of the plurality of first bonding electrodes is embedded in the protection layer; and another portion of each of the plurality of first bonding electrodes protrudes out of the protection layer; the conductive deformation layer covers a surface of the another portion of each of the plurality of first bonding electrodes.

17. A method of manufacturing a display panel, comprising:
providing a silicon-based driver substrate; wherein the silicon-based driver substrate comprises a plurality of first bonding electrodes;
providing a glass substrate; wherein the glass substrate comprises a first surface and a second surface opposite to the first surface; the glass substrate defines a plurality of conductive through holes extending from the first surface to the second surface; the plurality of conductive through holes comprises a plurality of first conductive through holes;
coating a deformation material on at least a sidewall surface of each of the plurality of first bonding electrodes to form a deformation layer;
bonding a side of the second surface of the glass substrate to the silicon-based driver substrate; and embedding each of the plurality of first bonding electrodes coated with the deformation layer into a respective one of the plurality of first conductive through holes;
filling a conductive material into the plurality of first conductive through holes to form a plurality of first bonding portions; and electrically connecting each of the plurality of first bonding portions to a respective one of the plurality of first bonding electrodes;
depositing a plurality of anode electrodes, a plurality of organic light emitting layers and a plurality of cathode electrodes sequentially on the first surface of the glass substrate to form a plurality of light emitting units; electrically connecting, through the respective first conductive through hole, each of the plurality of first bonding portions to a respective one of the plurality of anode electrodes.

18. The method according to claim 17, wherein,
the deformation layer is a conductive deformation layer, the deformation material is a conductive deformation material; the coating a deformation material on at least a sidewall surface of each of the plurality of first bonding electrodes to form a deformation layer, comprises:
coating the conductive deformation material on the sidewall surface of each of the plurality of first bonding electrodes to form a first conductive deformation layer; coating the conductive deformation material on a top wall surface of each of the plurality of first bonding electrodes to form a second conductive deformation layer; wherein a thickness of the second conductive deformation layer is greater than or equal to a thickness of the first conductive deformation layer.

19. The method according to claim 17, wherein,
the deformation layer is a conductive deformation layer, the deformation material is a conductive deformation material; the coating a deformation material on at least a sidewall surface of each of the plurality of first bonding electrodes to form a deformation layer, comprises:
coating the conductive deformation material on a sidewall surface of each of the plurality of first bonding electrodes to form a first conductive deformation layer; depositing the conductive deformation material on a sidewall surface of each of the plurality of first conductive through holes and removing a portion of the conductive material located near the second surface, so as to form a third conductive deformation layer.

20. The method according to claim 17, wherein, a surface of each other plurality of first bonding electrodes is roughened, and a surface roughness of each other plurality of first bonding electrodes is greater than or equal to 0.2 μm and is less than or equal to 0.4 μm.
